(19) United States
(12) Patent Application Publication
(10) Pub. No.: US 2023/0121340 A1
(43) Pub. Date: Apr. 20, 2023

(54) VERTICAL CAVITY SURFACE EMITTING LASER DIODE (VCSEL) WITH SMALL DIVERGENCE ANGLE

(71) Applicant: VISUAL PHOTONICS EPITAXY CO., LTD., Taoyuan City (TW)

(72) Inventors: Van-Truoung Dai, Vinhphuc province (VN); Yu-Chung Chin, Taoyuan City (TW); Chao-Hsing Huang, Taoyuan City (TW)

(21) Appl. No.: 17/966,544

(22) Filed: Oct. 14, 2022

(30) Foreign Application Priority Data
Oct. 14, 2021 (TW) 110138211

(51) Int. Cl. H01S 5/183

(52) U.S. Cl. CPC H01S 5/1833; H01S 5/18394; H01S 5/18397; H01S 5/18305

(57) ABSTRACT

Provided is a vertical cavity surface emitting laser diode (VCSEL) with a small divergence angle. The VCSEL includes a multi-layer structure on a substrate. The multi-layer structure includes an active region and current confinement layers. Each of the current confinement layers has an optical aperture (OA). When the area of the OA of the current confinement layer outside the active region is larger than the areas of the OAs of the current confinement layers inside the active region, such that the VCSEL has a small divergence angle in the short pulse mode.

### CROSS-REFERENCE TO RELATED APPLICATION

This application claims priority under 35 U.S.C. 119(a) to Taiwanese Application Serial No. 110138211, filed on Oct. 14, 2021; the entirety of the above-mentioned patent application is hereby incorporated by reference herein and made a part of this specification.

### TECHNICAL FIELD

The technical field relates to a vertical cavity surface emitting laser diode (VCSEL) with multiple current confinement layers.

### BACKGROUND

Laser light sources such as vertical cavity surface emitting laser diodes (VCSELs) are now commonly used as light sources for 3D sensing or optical communications. If the optical output power and power conversion efficiency of a VCSEL can be further improved, the 3D sensing or optical communications can save more power or reduce the chip area to reduce cost. In addition, the application of the VCSEL can also be extended to light detection and ranging (LiDAR), Virtual Reality (VR), Augmented Reality (AR), Direct Time-of-Flight (dTOF) sensors or other applications.

The US Patent Application (US 2020/0403379 A1) describes that the optical output power and power conversion efficiency (PCE) of the VCSEL are significantly increased if the area of the optical apertures (OAs) of the current confinement layers in the active region is different from the area of the OA of the current confinement layer outside the active region.

### SUMMARY

However, the above US patent application does not disclose that when the area of the OA of the current confinement layer outside the active region is larger than the areas of the OAs of the current confinement layers inside the active region, such that the VCSEL has a small divergence angle. Specifically, the VCSEL has a small divergence angle in the short pulse mode.

According to one embodiment, the present disclosure provides a vertical cavity surface emitting laser diode (VCSEL), including a multi-layer structure on a substrate, wherein the multi-layer structure includes: an active region, including a first active layer and a second active layer; a tunnel junction disposed between the first active layer and the second active layer for carrier recycling and connecting the first active layer and the second active layer in series; a first current confinement layer disposed outside the active region, wherein the first current confinement layer at least has a first optical aperture (OA), and the first OA is an uninsulated portion of the first current confinement layer; and a second current confinement layer disposed inside the active region, wherein the second current confinement layer at least has a second OA, the second OA is an uninsulated portion of the second current confinement layer, wherein an area of the first OA is not equal to an area of the second OA, and the area of the first OA is larger than the area of the second OA.

According to another embodiment, provided is a vertical cavity surface emitting laser diode (VCSEL), including: a multi-layer structure on a substrate, wherein the multi-layer structure includes: an active region, including: a first active layer, a second active layer, and a third active layer, wherein the second active layer is disposed between the first active and the second active layer; a first tunnel junction is disposed between the first active layer and the second active layer for carrier recycling and connecting the first active layer and the second active layer; a second tunnel junction is disposed between the second active layer and the third active layer for carrier recycling and connecting the second active layer and the third active layer; a first current confinement layer, disposed outside the active region, wherein, the first current confinement layer at least has a first optical aperture (OA) and the first OA is an uninsulated portion of the first current confinement layer; and a second current confinement layer, disposed inside the active region, wherein the second current confinement layer at least has a second OA, and the second OA is an uninsulated portion of the second current confinement layer, wherein an area of the first OA is not equal to areas of the second OA, and the area of the first OA is larger than the area of the second OA.

When the area of the first OA outside the active region is larger than one of the OAs (the second OA) inside the active region, and the first OA is disposed close to the light-emitting surface of the VCSEL, such that the VCSEL has a small divergence angle.

### BRIEF DESCRIPTION OF THE DRAWINGS

FIG. 1a is a schematic diagram showing that one of two current confinement layers is disposed inside the active region according to one embodiment of the present disclosure, wherein the optical aperture (OA) of the current confinement layer outside the active region is smaller than that of the current confinement layer inside the active region.

FIG. 1B is a schematic diagram showing that one of two current confinement layers is disposed inside the active region according to one embodiment of the present disclosure, wherein the OA of the current confinement layer outside the active region is greater than that of the current confinement layer inside the active region.

FIG. 1c is a schematic diagram showing that one of two current confinement layers is disposed inside the active region according to one embodiment of the present disclosure, wherein the OAs of the two current confinement layers are approximately equal or close to each other.

FIG. 1d is a detailed schematic diagram showing a possible structure of the active region of FIG. 1a.

FIG. 2 is a schematic diagram showing that the number of active layers is greater than the number of current confinement layers according to one embodiment of the present disclosure.

FIG. 3a shows a schematic diagram of a VCSEL including three current confinement layers and two active layers according to one embodiment of the present disclosure, wherein the OAs of the three current confinement layers are not equal.

FIG. 3b shows a schematic diagram of a VCSEL including three current confinement layers and two active layers, wherein the OAs of the three current confinement layers are approximately equal or close to each other.

FIG. 3c is a detailed schematic diagram showing a possible structure of the active region of FIG. 3a.

FIG. 4a shows a schematic diagram of a VCSEL including three current confinement layers and three active layers according to one embodiment of the present disclosure, wherein the OAs of the three current confinement layers are not equal.

FIG. 4b shows a schematic diagram of a VCSEL including three current confinement layers and three active layers according to one embodiment of the present disclosure, wherein the areas of the second OA and the third OA are approximately equal or close to each other, and the first OA outside the active region is smaller than the second OA or the third OA inside the active region.

FIG. 4c shows a schematic diagram of a VCSEL including three current confinement layers and three active layers according to one embodiment of the present disclosure, wherein the OAs of the three current confinement layers are approximately equal or close to each other.

FIG. 5a shows a schematic diagram of a VCSEL including four current confinement layers and three active layers according to one embodiment of the present disclosure, wherein the relationship among the first OA to the fourth OA is from small to large.

FIG. 5b shows a schematic diagram of a top-emitting VCSEL including four current confinement layers and three active layers according to one embodiment of the present disclosure, wherein the area of the third OA is larger than the areas of the first, second and fourth OAs.

FIG. 5c shows a schematic diagram of a bottom-emitting VCSEL including four current confinement layers and three active layers according to one embodiment of the present disclosure, wherein the area of the fourth OA is larger than the areas of the first, second and third OAs.

FIG. 5d shows a schematic diagram of a VCSEL including four current confinement layers and three active layers according to one embodiment of the present disclosure, wherein the relationship among the first OA to the fourth OA is from large to small.

FIG. 6a shows a schematic diagram of a top-emitting VCSEL including six current confinement layers and six active layers according to one embodiment of the present disclosure, wherein the area of the first OA is greater than the areas of the second OA to the sixth OA.

FIG. 6b shows a schematic diagram of a top-emitting VCSEL including six current confinement layers and six active layers according to one embodiment of the present disclosure, wherein the area of the first OA is equal to the areas of the second OA to the sixth OA.

FIG. 7 is a graph showing the far field profiles of the VCSEL of FIG. 6a and the VCSEL of FIG. 6b.

### DESCRIPTION OF THE EMBODIMENTS

The embodiment of the present disclosure is described in detail below with reference to the drawings and element symbols, such that persons skilled in the art is able to implement the present application after understanding the specification of the present disclosure.

Specific examples of components and arrangements are described below to simplify the present disclosure. These are, of course, merely examples and they are not intended to limit the scope of the present disclosure. In the present disclosure, for example, when a layer formed above or on another layer, it may include an exemplary embodiment in which the layer is in direct contact with the another layer, or it may include an exemplary embodiment in which other devices or epitaxial layers are formed between thereof, such that the layer is not in direct contact with the another layer. In addition, repeated reference numerals and/or notations may be used in different embodiments, these repetitions are only used to describe some embodiments simply and clearly, and do not represent a specific relationship between the different embodiments and/or structures discussed.

Further, spatially relative terms, such as “underlying,” “below,” “lower,” “overlying,” “above,” “upper” and the like, may be used herein for ease of description to describe one device or feature's relationship to another device(s) or feature(s) as illustrated in the figures and/or drawings. The spatially relative terms are intended to encompass different orientations of the device in use or operation in addition to the orientation depicted in the figures and/or drawings.

Moreover, certain terminology has been used to describe embodiments of the present disclosure. For example, the terms “one embodiment,” “an embodiment,” and “some embodiments” mean that a particular feature, structure or characteristic described in connection with the embodiment is included in at least one embodiment of the present disclosure. Therefore, it is emphasized and should be appreciated that two or more references to “an embodiment” or “one embodiment” or “an alternative embodiment” in various portions of the present disclosure are not necessarily all referring to the same embodiment.

Furthermore, the particular features, structures or characteristics may be combined in any suitable manner in one or more embodiments of the present disclosure. Further, for the terms “including”, “having”, “with”, “wherein” or the foregoing transformations used herein, these terms are similar to the term “comprising” to include corresponding features.

In addition, a “layer” may be a single layer or a plurality of layers; and “a portion” of an epitaxial layer may be one layer of the epitaxial layer or a plurality of adjacent layers.

In various implementations, the laser diode can be optionally provided with a buffer layer according to actual needs, and in some embodiments, the materials of the buffer and the substrate may be the same. Whether the buffer is provided is not substantially related to the technical characteristics to be described in the following embodiments and the effects to be provided. Accordingly, for the sake of a brief explanation, the following embodiments are only described with a laser diode having a buffer layer, and no further description is given to a laser without a buffer layer; that is, the following embodiments can also be applied by replacing a laser diode without a buffer.

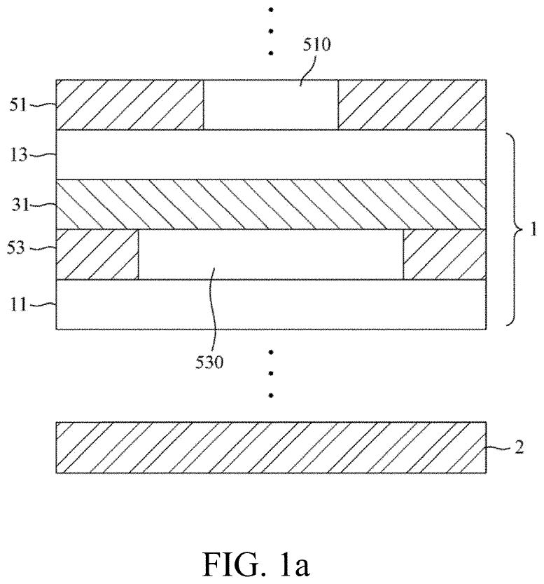

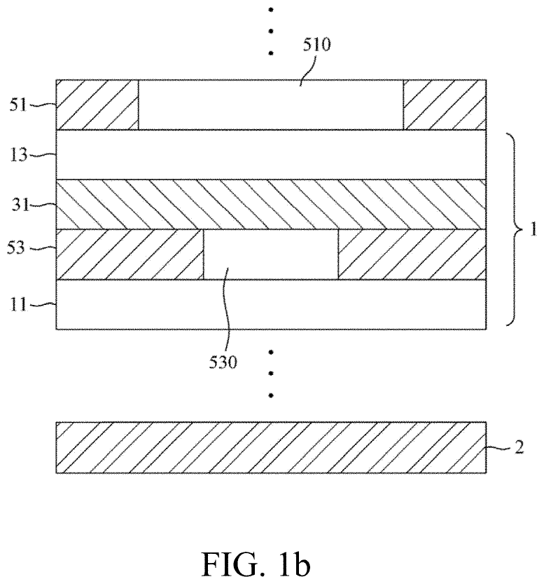

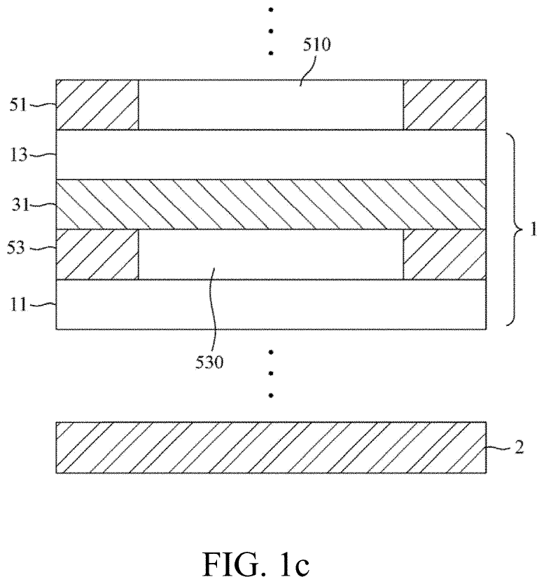

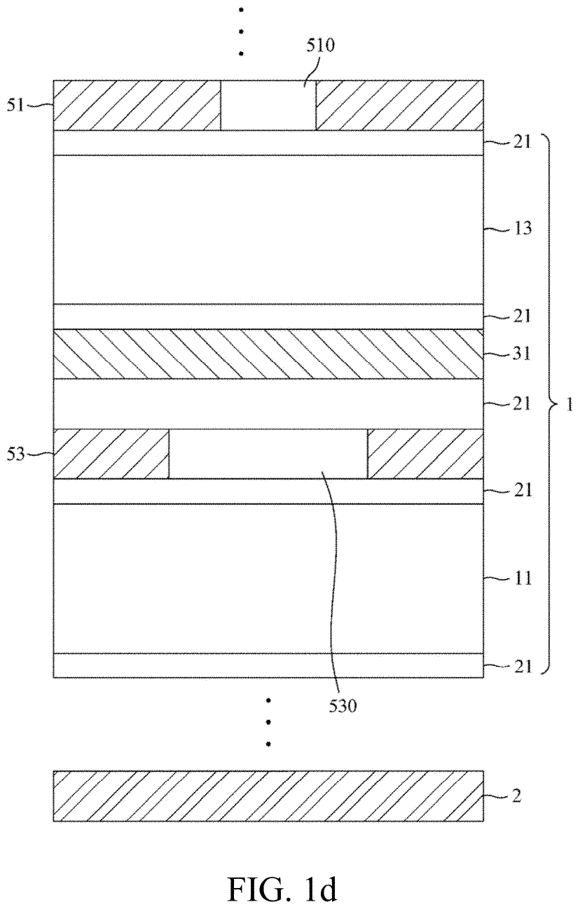

Referring to FIGS. 1a to 1d, a vertical cavity surface emitting laser diode (VCSEL) is provided in the present disclosure. The typical manufacturing method of a VCSEL is to epitaxially grow a multi-layer structure 1 on a substrate 2, and the finished product of a VCSEL is not necessary to have a substrate 2. That is, the VCSEL can retain the substrate 2 or remove the substrate 2. The multi-layer structure 1 includes an active region, and the active region includes one or a plurality of active layers. If the active region includes a plurality of active layers, a tunnel junction is arranged between every two adjacent active layers.

Each embodiment of the present disclosure is to provide two or more current confinement layers in the multi-layer structure. Each current confinement layer has at least one optical aperture (OA). The OA is the uninsulated portion of each current confinement layer, while the insulated portion of each current confinement layer (as shown by the diagonal lines of the current confinement layer 51 of FIG. 1a) should be understood as the portion with a high resistance of the current confinement layer.

The number of current confinement layers may be three, four, five or more layers. In different embodiments, the disposition or combination of current confinement layers will be different. Therefore, in order to distinguishing the position of each current confinement layer, in the case of two current confinement layers, one of the current confinement layers is called the first current confinement layer, and the other one is called the second current confinement layer. In the case of three or more current confinement layers, they are called the first current confinement layer, the second current confinement layer, the third current confinement layer, and so on. Similarly, in order to distinguish the position of each active layer of the multiple active layers in the VCSEL, the active layers of the multiple active layers are called the first active layer, the second active layer, the third active layer . . . to the Nth active layer, and so on.

In order to simplify the drawings, most of the drawings only show epitaxial layers such as active layers, tunnel junctions and current confinement layers, etc., the other epitaxial layers such as upper DBR layers, lower DBR layers, spacer layers, ohmic contact layers, etc. are not displayed even if these epitaxial layers are a necessary or preferred structure of a VCSEL. The spacer layer is generally formed above and/or below the active layer, current confinement layer, tunnel junction or other epitaxial layers. The spacer layer may be selectively disposed according to actual needs, and the material, material composition, thickness, doping and doping concentration of each spacer layer may also be adjusted appropriately in accordance with actual needs.

The following uses some representative embodiments to explain how two or more current confinement layers are specifically arranged in a VCSEL.

### Embodiment 1

In terms of the main structure shown in FIGS. 1a, 1b and 1c, the first current confinement layer 51 with the first OA 510 is disposed on the active region 1. The tunnel junction 31 and the second current confinement layer 53 with the second OA 530 are disposed between the first active layer 11 and the second active layer 13 in the active region 1. The tunnel junction 31 is between the first current confinement layer 51 and the second current confinement layer 53.

According to the structure of FIG. 1a, since the tunnel junction 31, the second current confinement layer 53 and the first active layer 11 are sequentially under the second active layer 13, in this configuration, when current flows from the first OA 510 and into the first active layer 11 through the second OA 530. The epitaxial layer above the first current confinement layer 51 is mainly composed of a P-type epitaxial layer. If the epitaxial layer above the first current confinement layer 51 further includes an N-type epitaxial layer (not shown), the N-type epitaxial layer and the first current confinement layer 51 can be connected in series with the tunnel junction or form an indirect contact through the tunnel junction.

In terms of OA areas (i.e., opening areas), the OA area of the first OA is not equal to the OA area of the second OA, as shown in FIGS. 1a and 1b. As shown in FIG. 1c, when the OA areas of the first OA 510 and the second OA 530 are sufficiently large, the OA areas of the first OA 510 and the second OA 530 may be substantially equal or close to each other.

FIG. 1d is the detailed structure of FIG. 1a. In FIG. 1d, the spacer layer 21 is provided above and below the active layers 11, 13, the current confinement layers 53(51) and the tunnel junction 31. Current I mainly passes through the first OA 510 for carrier confinement and/or optical confinement, the second active layer 13 for emitting light, the tunnel junction 31 for carrier recycling and/or connecting two active layers in series, the second OA 530 for carrier confinement and/or optical confinement, and the first active layer 11 for emitting light.

After the current I enters the second active layer 13 from the first OA 510, the current I flowing through the second active layer 13 and the tunnel junction 31 becomes less spreading, such that the carrier confinement of the second active layer 13 becomes better. After the current I passes through the second OA 530 of the second current confinement layer 53, the current I is more easily confined to the area of the first active layer 11 corresponding to the second OA 530, such that the carrier and/or optical confinement of the first active layer 11 and the second active layer 13 can be significantly improved, thereby improving the optical output power, slope efficiency, or power conversion efficiency (PCE) of the VCSEL.

By disposing the second current confinement layer between two active layers, the carrier confinement effect of the second current confinement layer can act on the second active layer and the first active layer above and below the second current confinement layer. In this way, not only can the carrier confinement and/or optical confinement of the first active layer be improved, but also the carrier confinement and/or optical confinement of the second active layer can be further improved. As such, the optical output power of the VCSEL can be significantly increased as the number of active layers is increased, and slope efficiency or the PCE of the VCSEL can also be significantly improved as the number of active layers is increased.

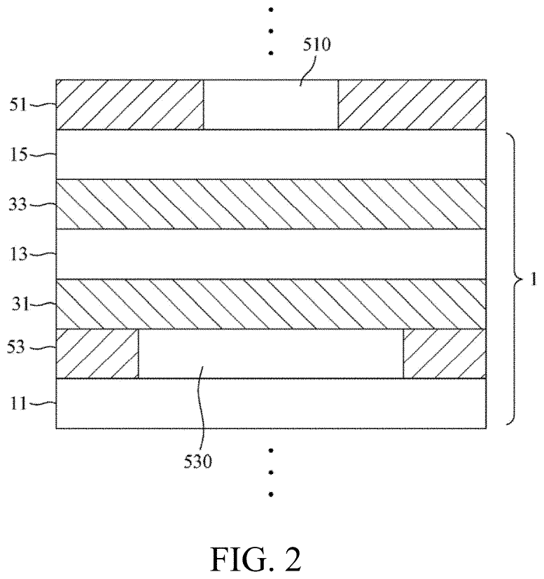

In some embodiments, the number of current confinement layers may be less than the number of active layers. As shown in FIG. 2, the number of current confinement layers may be two layers. The number of active layers in the active region may be three layers, but not limited thereto. The number of active layers may be four or more layers. If the optical output power, slope efficiency or PCE of the VCSEL needs to be further improved, the number of current confinement layers may be the same as that of the active layers. The number of current confinement layers may also be more than the number of active layers. For example, the number of current confinement layers may be more than the number of active layers by one more layer or more than two layers, but the total resistance of all current confinement layers cannot be too large, otherwise it may affect the performance or PCE of the VCSEL.

Another factor that determines the resistance of the current confinement layer is the area of the OA of the current confinement layer. In principle, the OA areas of two OAs or the OA areas of the OAs may be unequal. However, if the OA areas of two OAs or the OA areas of the OAs are large enough, since the resistance is small, the OA areas of two OAs or the OA areas of the OAs may still be approximately equal or close to each other.

In FIGS. 1a and 1b, the OA areas of the first OA and the second OA are not equal. The ratio of the OA area of the first OA to the OA area of the second OA may be between 0.1 and 1 (excluding the ratio of 1). The total resistance of the current confinement layers is not too large so as not to significantly affect the performance or PCE of the VCSEL. Preferably, the ratio of the OA area of the first OA to the OA area of the second OA may be between 0.2 and 1, between 0.3 and 1, between 0.5 and 1, between 0.54 and 1, between 0.6 and 1, between 0.65 and 1, between 0.7 and 1, between 0.75 and 1 or between 0.8 and 1. In addition to maintaining better carrier confinement and/or optical confinement, the total resistance of two current confinement layers is relatively small so as to help improve the performance or PCE of the VCSEL. The specific ratio of the area of the first OA to the area of the second OA is 0.5, 0.6, 0.7, 0.8, 0.9, 1.0, 1.1, 1.2, 1.3, 1.4, 1.5, 1.6, 1.7, 1.8, 1.9 or 2.0.

In the case where the areas of the first OA and the second OA are sufficiently large, since the resistance of the first current confinement layer and the second current confinement layer are relatively small, the total resistance of both thereof is not easily too large. Accordingly, the areas of the first OA and the second OA may be approximately equal or even equal. For example, if the areas of the first OA and the second OA are not less than 30 μm², the area of the first OA may be approximately equal to, nearly equal, or even exactly equal to that of the second OA. In some embodiments, the smaller area of each current confinement layer may also be greater than 40 μm² or 50 μm².

According to the previous paragraph, if the total resistance of current confinement layers can be appropriately reduced, it is easy to maintain or improve the PCE of the VCSEL, and the first active layer and the second active layer may also have better carrier confinement and optical confinement, thereby improving the performance, slope efficiency or PCE of the VCSEL. The VCSEL may be a top-emitting VCSEL or a bottom-emitting VCSEL.

In the case where the areas of both the first OA and the second OA are sufficiently large, preferably, the ratio of the area of the first OA to the area of the second OA is X, where 0.3≤X≤1. Therefore, in one case, the areas of the first OA and the second OA are approximately equal or close to each other; that is, the ratio of the area of the first OA to the area of the second OA is close to or may be exactly 1 (X≈1 or X=1). In the other case, when the areas of the first OA and the second OA are different, the ratio of the area of the first OA to the area of the second OA is greater than or equal to 0.3 and less than 1 (0.3≤X<1). The smaller area between the first OA and the second OA is the numerator of the ratio, and the larger area between both thereof is the denominator of the ratio.

### Embodiment 2

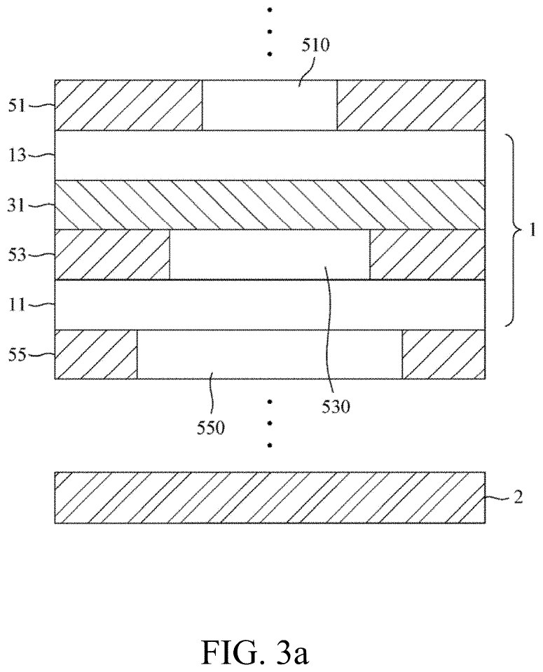

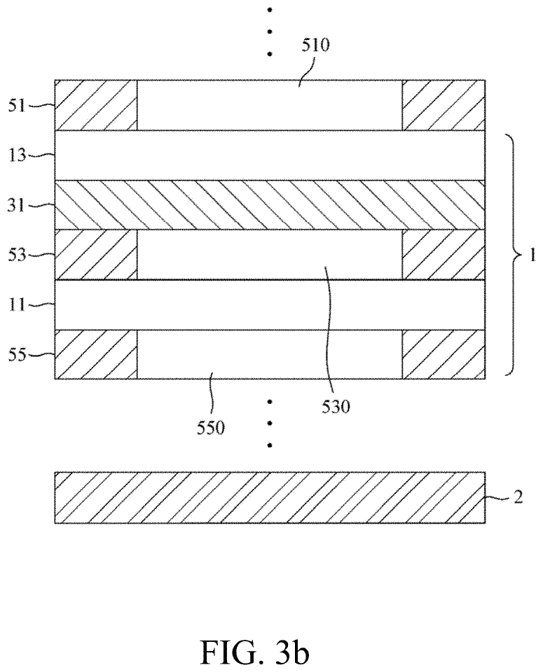

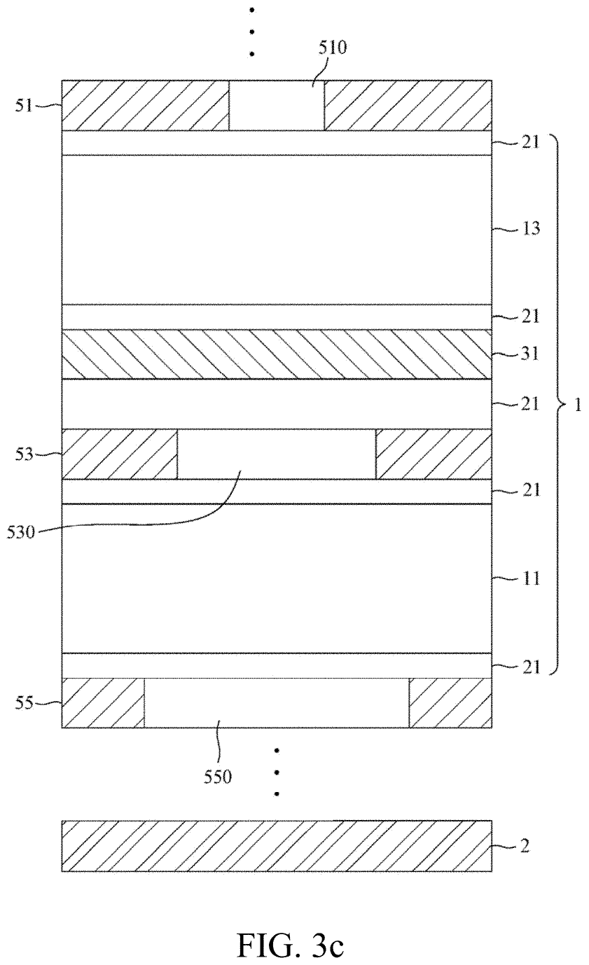

As shown in FIG. 3a, the VCSEL includes three current confinement layers 51, 53, 55 and two active layers 11, 13. The areas of the three current confinement layers 51, 53, 55 are not equal to each other, and the areas of the first, second and third OAs are a small area, a medium area and a large area, respectively. The structure shown in FIG. 3a is only an example. The areas of the first, second and third OAs may also be a large area, a medium area and a small area, respectively, may be a small area, a medium area and a medium area, respectively, or may be various other appropriate combinations. It is worth noting that when the area of the first OA outside the active region is larger than the area of the second OA or third OA inside the active region, and the first OA is disposed close to the light-emitting surface of the VCSEL, the VCSEL has a small divergence angle. Preferably, the ratio of the area of the first OA to the area of the second OA, the ratio of the area of the second OA to the area of the third OA or the ratio of the area of the third OA to the first OA may be between 0.2 and 1, between 0.3 and 1, between 0.5 and 1, between 0.54 and 1, between 0.6 and 1, between 0.65 and 1, between 0.7 and 1, between 0.75 and 1 or between 0.8 and 1. The specific ratio thereof may be 0.5, 0.6, 0.7, 0.8, 0.9, 1.0, 1.1, 1.2, 1.3, 1.4, 1.5, 1.6, 1.7, 1.8, 1.9 or 2.0.

As long as the carrier confinement and/or optical confinement of the active layer as well as the PCE of the VCSEL are not significantly affected, the area of OA of the current confinement layer outside the active region 1 may be as large as possible, as shown in the third OA 550 of FIG. 3a. In the VCSEL provided with multiple current confinement layers, the total resistance of current confinement layers is less likely to be too large such that the performance of the VCSEL are also less likely to be affected.

### Embodiment 3

In the case where the VCSEL includes three current confinement layers or even more current confinement layers, if the areas of some OAs or all OAs are large enough, that is, the total resistance of the current confinement layers will not be too large, the areas of some OAs or all OAs may not be equal to each other, and two or each of some OAs or all OAs may also be approximately equal or close to each other.

Taking FIG. 3b as an example, if the smallest area among the first, second and third OAs is greater than 30 μm² (40 μm²/50 μm²), the areas thereof may even be equal to each other. In principle, as long as the total resistance of the current confinement layers does not significantly affect the PCE of the VCSEL, one or some of the current confinement layers may be less than 30 μm² (40 μm²/50 μm²).

Further, two of the first, second and third OAs have a ratio X, where 0.3≤X≤1. Accordingly, the areas thereof may be equivalent, that is, the ratio X is close to or may be exactly equal to 1 (X≈1 or X=1). When the areas of two thereof or all three OAs are different, the ratio X is greater than or equal to 0.3 and less than 1 (0.3≤X<1). In such case, the smaller area among two thereof is numerator of the ratio.

FIG. 3c is the detailed structure of FIG. 3a. In FIG. 3c, a spacer layer 21 is provided above and below the active layers 11, 13, the tunnel junction 31 and the current confinements 51, 53, 55, but FIG. 3c is only an example. Other modified or derived implementation structures may also be included in the present disclosure. The main structures in FIG. 3b and FIG. 3a are also the same. In FIG. 3b, the spacer layer may also be provided in the foregoing manner.

### Embodiment 4

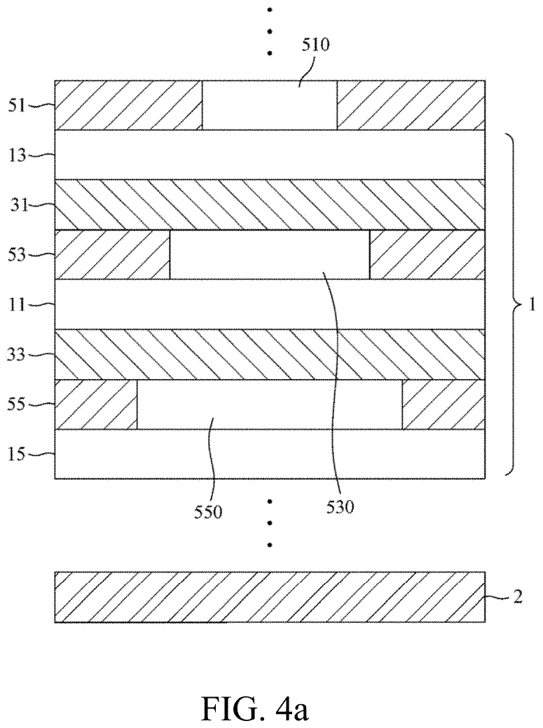

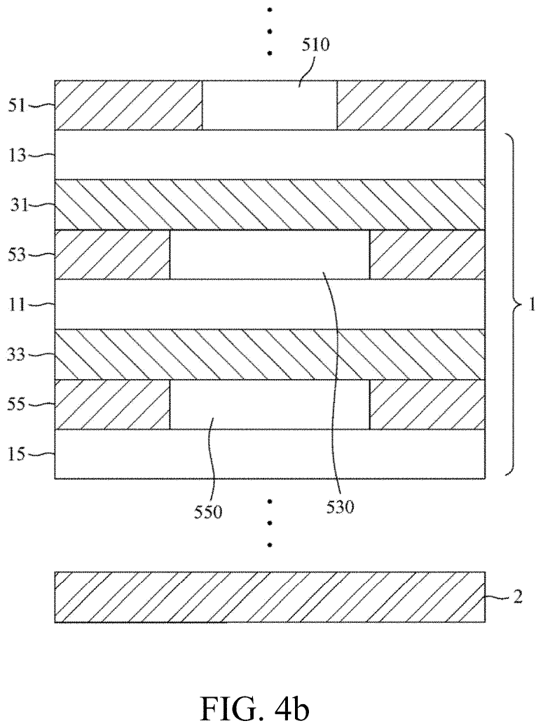

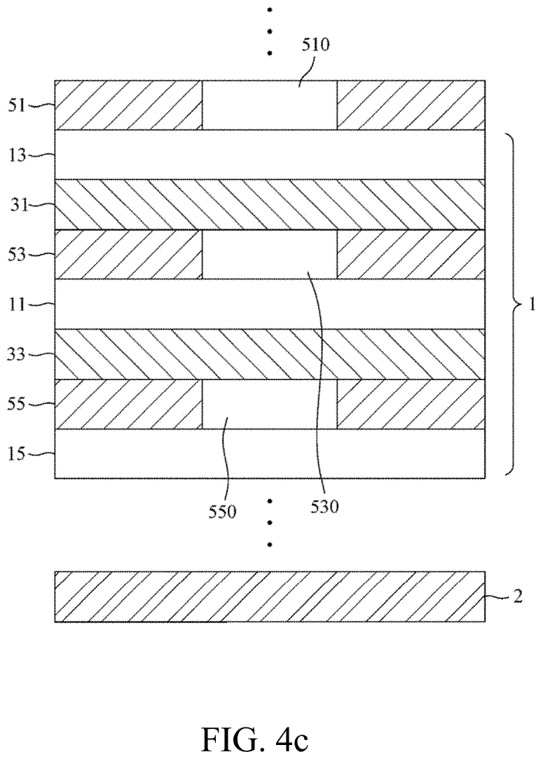

As shown in FIG. 4a, FIG. 4a is based on FIG. 3a, and further includes a third active layer 15 and a tunnel junction 33. The third active layer 15 is disposed below the first active layer 11, and a tunnel junction 33 and a third current confinement layer 55 are provided between the third active layer 15 and the first active layer 11. In addition, a tunnel junction 31 is disposed between the first current confinement layer 51 and the second current confinement layer 53, while the tunnel junction 33 is provided between the second current confinement layer 53 and the third current confinement layer 55.

In FIG. 4a, the areas of the first OA 510, the second OA 530 and the third OA 550 are a small area, a medium area and a large area, respectively. The structure shown in FIG. 4a is only an example. The areas of the first OA 510, the second OA 530 and the third OA 550 may also be a large area, a medium area and a small area, respectively, may be a small area, a large area and a medium area, or may be various other appropriate combinations. Alternatively, as shown in FIG. 4b, the area of the first OA 510 is small, and the areas of the second OA 530 and the third OA 550 are almost equal and larger than the area of the first OA 510. On the other hand, as shown in FIG. 4c, the areas of the first OA 510, the second OA 530 and the third OA 550 are approximately equal or equal.

A spacer or other epitaxial layers may further be provided above and/or below the active layer, current confinement layer or tunnel junction in FIGS. 4a-4c in accordance with actual needs.

### Embodiment 5

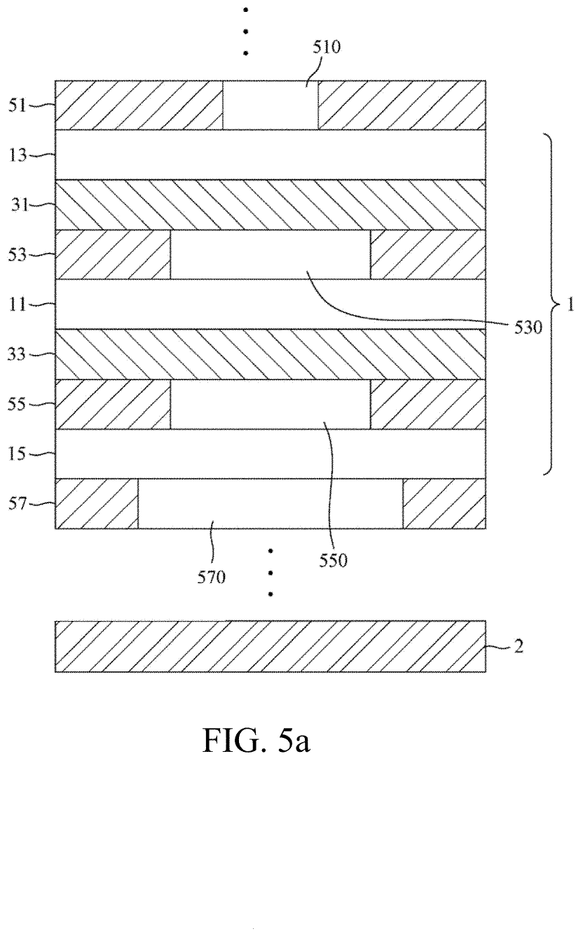

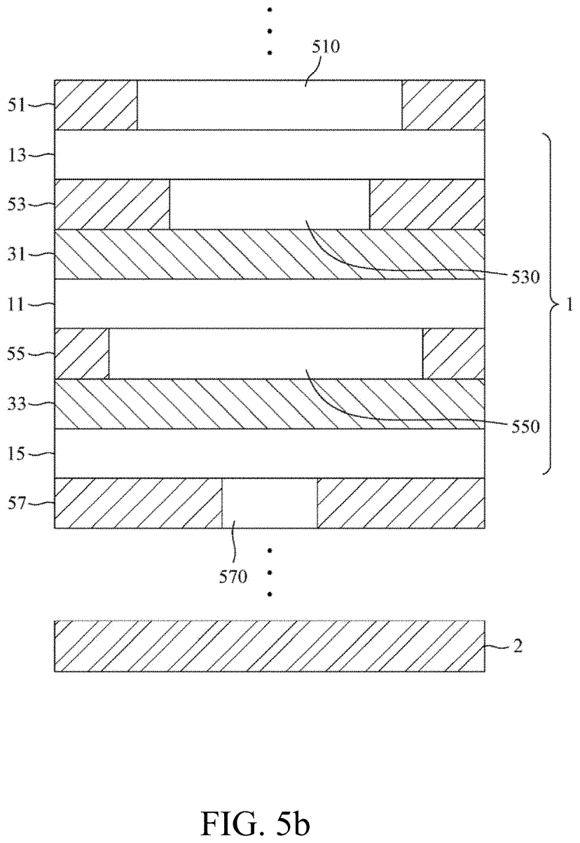

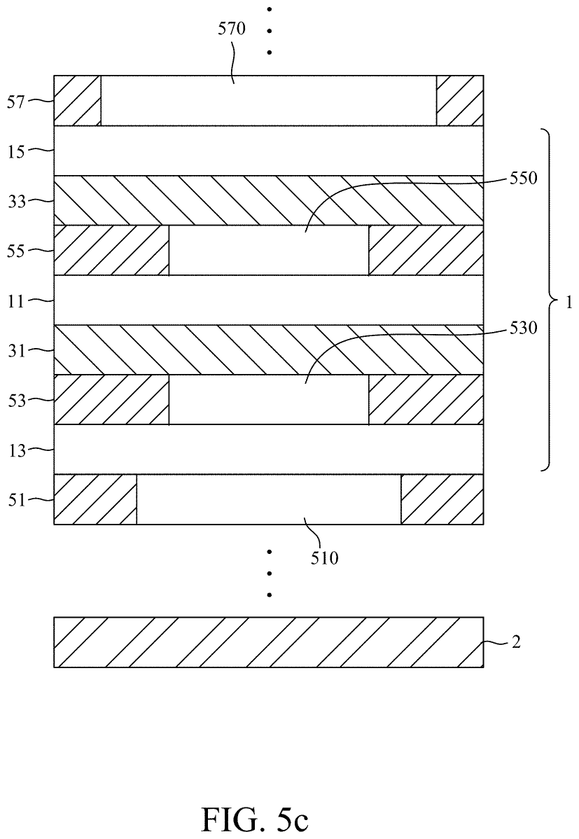

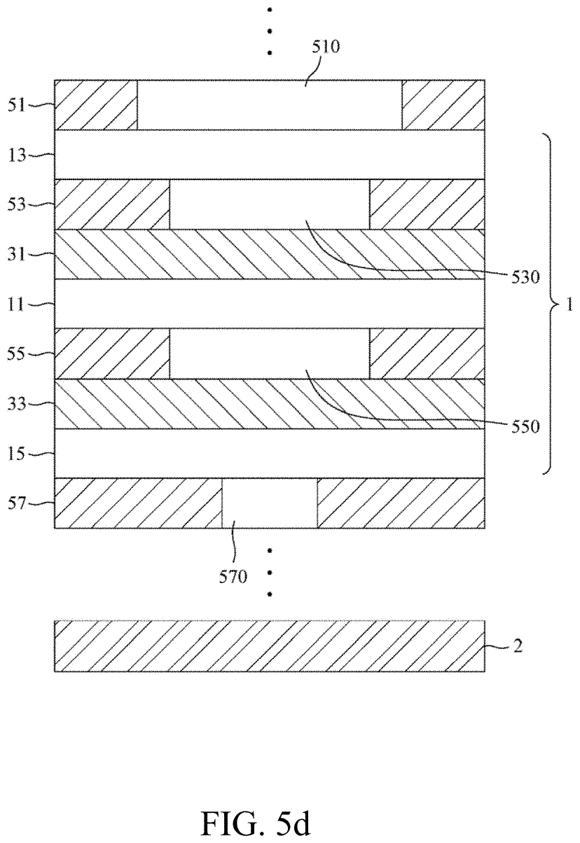

As shown in FIG. 5a, the VCSEL includes an active region 1 with three active layers 11, 13, 15, four current confinement layers 51, 53, 55, 57 and two tunnel junctions 31, 33. The first current confinement layer 51 and the fourth current confinement layer 57 are disposed above and below the active region 1. The tunnel junction 31 is provided between the first current confinement layer 51 and the second current confinement layer 53, and the tunnel junction 33 is provided between the second current confinement layer 53 and the third current confinement layer 55.

According to the arrangement relationship between the third current confinement layer 55 and the tunnel junction 33 of FIG. 5a, when current flows from the first OA 510, an epitaxial layer above the first current confinement layer 51 is mainly composed of a P-type epitaxial layer. If the epitaxial layer above the first current confinement layer 51 further includes an N-type epitaxial layer, a serial connection or indirect connection may be formed through a tunnel junction between the N-type epitaxial layer and the first current confinement layer 51.

FIG. 5b shows a schematic diagram of a top-emitting VCSEL. The top-emitting VCSEL has a top surface. In the embodiment of the top-emitting VCSEL, the first current confinement layer is disposed between the active region and the top surface of the VCSEL. Light is emitted from the top surface (not shown) of the top-emitting VCSEL. The top-emitting VCSEL includes four current confinement layers 51, 53, 55, 57 and three active layers 11, 13, 15 according to one embodiment of the present disclosure, wherein the area of the first OA 510 is larger than one of the second to fourth OAs 530, 550, 570, such that the VCSEL has a smaller divergence angle.

FIG. 5c shows a schematic diagram of a bottom-emitting VCSEL. In the embodiment of the bottom-emitting VCSEL, the first current confinement layer is disposed between the active region and the substrate. The bottom-emitting VCSEL includes four current confinement layers 51, 53, 55, 57 and three active layers 11, 13, 15 according to one embodiment of the present disclosure, wherein the area of the first OA 510 is larger than one of the second to fourth OAs 530, 550, 570, such that the VCSEL has a smaller divergence angle.

As shown in FIG. 5d, the VCSEL includes an active region 1 with three active layers 11, 13, 15 and four current confinement layers 51, 53, 55, 57 and two tunnel junctions 31, 33. The first current confinement layer 51 and the fourth current confinement layer 57 are disposed above and below the active region 1. According to the arrangement relationship between the tunnel junction 33 and the third current confinement layer 55 or the arrangement relationship between the tunnel junction 31 and the second current confinement layer 53 of FIG. 5d, current flows from the fourth OA 570. An epitaxial layer below the fourth current confinement layer 57 is mainly composed of a P-type epitaxial layer. If the epitaxial layer below the fourth current confinement layer 57 further includes an N-type epitaxial layer, a serial connection or indirect connection may be formed through a tunnel junction between the N-type epitaxial layer and the fourth current confinement layer 57.

In a modified embodiment, the area of the fourth OA of the fourth current confinement layer 57 (above the active region 1) of FIG. 5c may be very large. In such case, the total resistance of each current confinement layer is less likely to be too large, and the performance of the VCSEL is less likely to be affected.

A spacer or other epitaxial layers may further be provided above and/or below the active layer, current confinement layer and/or tunnel junction layer in FIG. 5a or FIG. 5d according to actual needs.

In the aforesaid embodiments, the OAs of the current confinement layers, such as the first OA 510, the second OA 530, the third OA 550, the fourth OA 570, the fifth OA 590, etc., are the portions of the current confinement layers that are not insulated. The insulation process may be appropriate insulation processes such as an oxidation process, an ion implantation process or an etching process. In principle, the insulation process is performed from the sides of the multi-layer structure to form the insulation portion of each current confinement layer. The size of the area of each OA can be determined by the oxidation process or the ion implantation process.

In general, the area of the OA is related to the parameters of the oxidation process, such as oxidation time or oxidation rate, etc. The oxidation rate is related to the material or material composition of each current confinement layer or the thickness of each current confinement layer. As such, if the current confinement layers need to form OAs of different sizes, different materials may be used for different current confinement layers, the same material may be used for different current confinement layers but the material composition are different, or the thicknesses of the current confinement layers are different.

In addition, the mesa type process or the non-planar type process may also be a factor that determines the size of an OA. In terms of mesa type process, the insulation process is carried out from the outer side of the mesa. If the mesa is probably narrow on the top and wide at the bottom (such as a trapezoid or ladder shape) or wide on the top and narrow at the bottom (not shown), even if the materials, material composition and thicknesses of current confinement layers are the same, that is, even under the same oxidation rate, the insulation portions of the current confinement layers will be almost the same, but the size of the OAs are different.

If the mesa is as shown in FIG. 1a, under the condition that the diameters of the upper or lower half of the mesa are approximately the same, if the areas of OAs of the current confinement layers are to be as consistent as possible, the materials, material composition and thicknesses of the current confinement layers can be the same. In this way, under the same oxidation rate, the areas of the current confinement layers may be more consistent.

For non-planar type process, multiple holes are formed in the multi-layer structure by wet etching or dry etching such that the holes are distributed in different positions of the current confinement layers. The insulation process is carried out by oxidation from the holes and oxidizing diffusion around. According to the actual need, the ion implantation process can be used after the oxidation process. The portions that are not subjected to the insulation process are the OAs at the end. Hence, the areas of the OAs are mainly determined or adjusted by controlling the number of holes, the distribution of holes or the ion implantation process such that the area of the OAs are significantly different or the areas of the OAs may be more consistent.

Without affecting the carrier confinement and optical confinement of the active layers, the insulation portions of the current confinement layers in the active region may be as small as possible, such as smaller than the insulation portions of the current confinement layers outside the active region. The less the insulation portions of the current confinement layers in the active region are, the less stress and defects in the active region it generates. The stress in the active region is smaller or there are fewer defects generated in the active region such that it is less likely to affect the reliability of a VCSEL. Preferably, the OAs of the current confinement layers are substantially circular, the OAs of the current confinement layers may be in the center regions of the current confinement layers, or the OAs of the current confinement layers correspond to each other.

The insulating region formed by the oxidation process can also improve the optical confinement of a VCSEL due to the change of the refractive index of the insulated portion of the current confinement layer and improve the performance of the VCSEL.

In some embodiments, the material of the current confinement layer has the characteristic of being easily oxidized. Preferably, the material of the current confinement layer contains aluminum or other easily oxidized materials, such as AlGaAs, AlGaAsP, AlAs, AlAsP, AlAsSb, AlAsBi, InAlAs or InAlAsSb.

### Embodiment 6

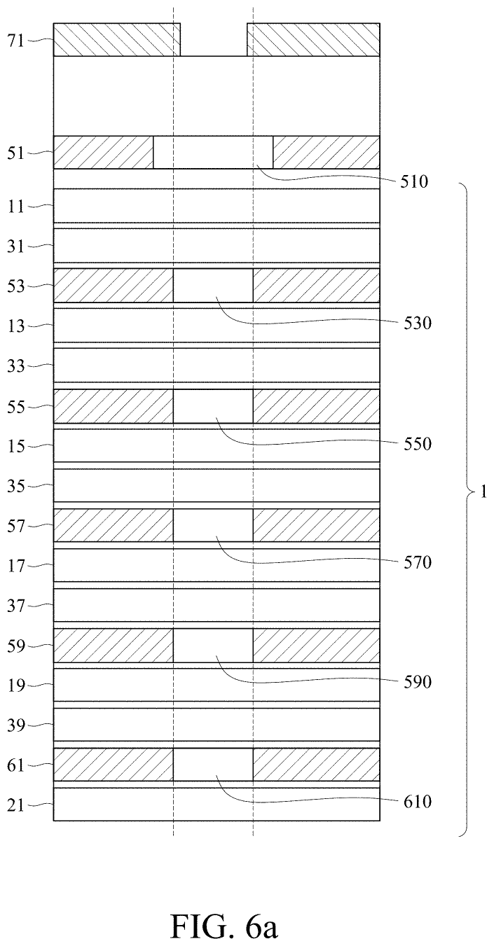

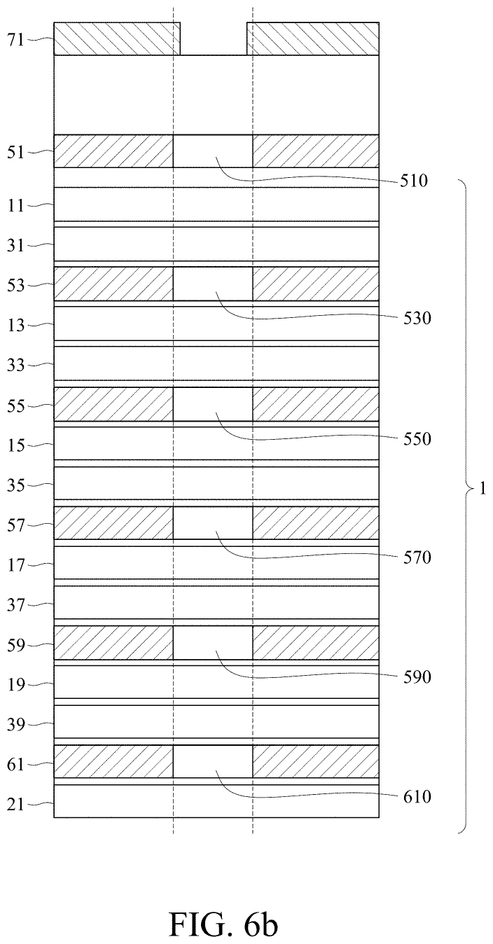

Referring to FIG. 6a, the multi-layer structure of the top-emitting VCSEL includes a first current confinement layer 51 and an active region 1. The first current confinement layer 51 is disposed above the active region 1. In addition, the active region 1 includes 6 active layers (i.e., the first active layer to the six active layer 11, 13, 15, 17, 19, 21), 5 tunnel junctions 31, 33, 35, 37, 39 and 5 current confinement layers in the active region (i.e., the second current confinement layer to the sixth current confinement layer 53, 55, 57, 59, 61.

As shown in FIG. 6a, the diameter of the first OA of the first current confinement layer is approximately 21.5 μm, and the diameters of the second OA to the sixth OA of the second current confinement layer to the sixth current confinement layer is approximately 20 μm.

As shown in FIG. 6a, a surface relief layer 71 with an opening (e.g., the diameter of the opening is approximately 18 μm) is the top layer of the VCSEL. The diameter of the opening of the surface relief layer 71 can be varied according to needs. It is worth mentioning that even though the diameter of the opening of the surface relief layer 71 of FIG. 6a is larger than the diameter of the first OA 510, the VCSEL of FIG. 6a still has a small divergence angle.

Referring to FIG. 6b, the VCSEL structure shown in FIG. 6b is similar to the VCSEL structure shown in FIG. 6a. The only difference is that the diameter of the first OA 510 is equal to the diameters of the second OA 530 to the sixth OA 610. That is, the diameter of the first OA 510 is 20 μm, and the diameters of the second OA 530 to the sixth OA 610 are also 20 μm.

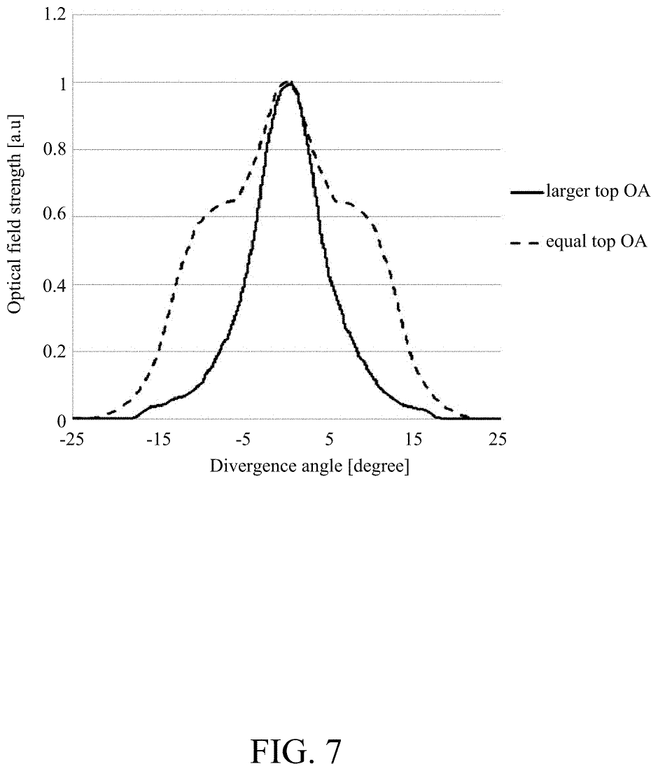

FIG. 7 is a schematic diagram showing the far field profiles of the VCSEL of FIG. 6a and the VCSEL of FIG. 6b. The far field profiles of the VCSEL of FIG. 6a and the VCSEL of FIG. 6b are measured at a bias voltage 15V in a 10 nano-second (ns) pulse mode. The far field angle full width half maximum of the structure of FIG. 6a (solid line of FIG. 7) is about 10 degrees, while the far field angle full width half maximum of the structure of FIG. 6b (dashed line of FIG. 7) is about 28 degrees. It is clear from FIG. 7 that the divergence angle of the dashed line is more than twice that of the solid line. As a result, the structure of FIG. 6a has a smaller divergence angle than the structure of FIG. 6b.

As such, in the present disclosure, a small divergence angle can be obtained in the short pulse mode.

In one or some embodiments, the VCSEL further includes another current confinement layer with an OA (not shown). The current confinement layer may be disposed inside or outside the active region 1. The area of the OA may be larger than or smaller than the area of the first OA.

In one or some embodiments, the active region 1 may include 8, 9 or 10 active layers or more than 10 active layers and 7, 8 or 9 tunnel junctions or more than 9 tunnel junctions.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A vertical cavity surface emitting laser diode (VCSEL), comprising:
a multi-layer structure on a substrate, wherein the multi-layer structure comprises:
an active region, comprising:
a first active layer and a second active layer;
a tunnel junction disposed between the first active layer and the second active layer for carrier recycling and connecting the first active layer and the second active layer in series;
a first current confinement layer disposed outside the active region, wherein the first current confinement layer at least has a first optical aperture (OA), and the first OA is an uninsulated portion of the first current confinement layer; and
a second current confinement layer disposed inside the active region, wherein the second current confinement layer at least has a second OA, and the second OA is an uninsulated portion of the second current confinement layer,
wherein an area of the first OA is not equal to an area of the second OA, and the area of the first OA is larger than the area of the second OA.

2. The VCSEL as claimed in claim 1, wherein the insulated portions of both the first current confinement layer and the second current confinement layer are made by an insulation process, and the insulation process is an oxidation process, an ion implantation process or an etching process.

3. The VCSEL as claimed in claim 1, wherein the first current confinement layer and/or the second current confinement layer is/are selected from the group consisting of AlGaAs, AlGaAsP, AlAs, AlAsP, AlAsSb, AlAsBi, InAlAs and InAlAsSb.

4. The VCSEL as claimed in claim 1, wherein a ratio of the area of the second OA to the area of the first OA is approximately between 0.5 and 1 (0.5≤X<1).

5. The VCSEL as claimed in claim 1, wherein a ratio of the area of the second OA to the area of the first OA is approximately between 0.54 and 1(0.54≤X<1).

6. The VCSEL as claimed in claim 1, wherein a ratio of the area of the second OA to the area of the first OA is approximately between 0.6 and 1(0.6≤X<1).

7. The VCSEL as claimed in claim 1, wherein the VCSEL is a top-emitting VCSEL or a bottom-emitting VCSEL.

8. The VCSEL as claimed in claim 7, wherein the VCSEL has a top surface away from the substrate, when the VCSEL is the top-emitting VCSEL, the first current confinement layer is disposed between the active region and the top surface of the VCSEL.

9. The VCSEL as claimed in claim 7, wherein when the VCSEL is the bottom-emitting VCSEL, the first current confinement layer is disposed between the active region and the substrate.

10. A vertical cavity surface emitting laser diode (VCSEL), comprising:
a multi-layer structure on a substrate, wherein the multi-layer structure comprises:
an active region, comprising:
a first active layer, a second active layer, and a third active layer, wherein the second active layer is disposed between the first active and the third active layer;
a first tunnel junction is disposed between the first active layer and the second active layer for carrier recycling and connecting the first active layer and the second active layer;
a second tunnel junction is disposed between the second active layer and the third active layer for carrier recycling and connecting the second active layer and the third active layer;
a first current confinement layer, disposed outside the active region, wherein, the first current confinement layer at least has a first optical aperture (OA) and the first OA is an uninsulated portion of the first current confinement layer; and
a second current confinement layer, disposed inside the active region, wherein the second current confinement layer at least has a second OA, and the second OA is an uninsulated portion of the second current confinement layer,
wherein an area of the first OA is not equal to an area of the second OA, and the area of the first OA is larger than the area of the second OA.

11. The VCSEL as claimed in claim 10, further comprising: a third current confinement layer disposed inside or outside the active region.

12. The VCSEL as claimed in claim 11, wherein the third current confinement layer at least has a third OA, and the third OA is an uninsulated portion of the third current confinement layer.

13. The VCSEL as claimed in claim 11, wherein when the third current confinement layer is disposed inside the active region, the third current confinement layer is disposed between the second active layer and the third active layer.

14. The VCSEL as claimed in claim 11, wherein the third current confinement layer is selected from the group consisting of AlGaAs, AlGaAsP, AlAs, AlAsP, AlAsSb, AlAsBi, InAlAs and InAlAsSb.

15. The VCSEL as claimed in claim 10, wherein the first current confinement layer or the second current confinement layer are selected from the group consisting of AlGaAs, AlGaAsP, AlAs, AlAsP, AlAsSb, AlAsBi, InAlAs and InAlAsSb.

16. The VCSEL as claimed in claim 10, wherein a ratio of the areas of the second OA and the first OA is approximately between 0.5 and 1 (0.5≤X<1).

17. The VCSEL as claimed in claim 10, wherein a ratio of the areas of the second OA and the first OA is approximately between 0.54 and 1(0.54≤X<1).

18. The VCSEL as claimed in claim 10, wherein a ratio of the areas of two of the first OA, the second OA and the third OA is approximately between 0.6 and 1. (0.6≤X<1).

19. The VCSEL as claimed in claim 10, wherein the active region comprises another six, seven or eight active layers.

20. The VCSEL as claimed in claim 10, wherein the VCSEL is a top-emitting VCSEL or a bottom-emitting VCSEL.

21. The VCSEL as claimed in claim 20, wherein the VCSEL has a top surface away from the substrate, when the VCSEL is the top-emitting VCSEL, the first current confinement layer is disposed between the active region and the top surface of the VCSEL.

22. The VCSEL as claimed in claim 20, wherein when the VCSEL is the bottom-emitting VCSEL, the first current confinement layer is disposed between the active region and the substrate.
